(19) United States
(12) Patent Application Publication
(10) Pub. No.: US 2017/0294272 A1
(43) Pub. Date: Oct. 12, 2017

(54) DYE-SENSITIZED SOLAR PANEL

(71) Applicant: KING SAUD UNIVERSITY, RIYADH (SA)

(72) Inventors: MANAL AHMED GASMELSEED AWAD, RIYADH (SA); AWATIF AHMED HENDI, RIYADH (SA); KHALID MUSTAFA OSMAN ORTASHI, RIYADH (SA); NAWAL AHMAD ABDU MADKHALI, RIYADH (SA)

(21) Appl. No.: 15/587,321

(22) Filed: May 4, 2017

Related U.S. Application Data
(63) Continuation-in-part of application No. 15/097,257, filed on Apr. 12, 2016.

(51) Int. Cl. H01G 9/20; H01L 51/00; C09B 61/00; H01G 9/00

(52) U.S. Cl. CPC H01G 9/2059; H01G 9/2013; H01G 9/2068; H01G 9/2009; H01G 9/0029; H01L 51/0093; C09B 61/00

(57) ABSTRACT

A dye-sensitized solar panel includes a titanium nanoparticle layer and a plant-derived photo-sensitizer supported on the titanium nanoparticle layer. The photo-sensitizer can be extracted from chard (the cicla cultivar group of B. vulgaris subsp. cicla), and the titanium nanoparticle layer includes titanium nanoparticles synthesized using henna (Lawsonia inermis). The titanium nanoparticle layer can, in addition to titanium nanoparticles, include zinc oxide nanoparticles.

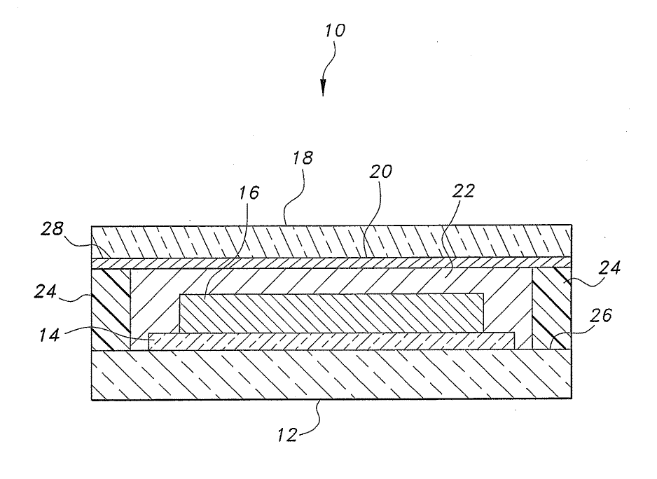

### CROSS-REFERENCE TO RELATED APPLICATION

This application is a continuation-in-part of U.S. patent application Ser. No. 15/097,257, filed on Apr. 12, 2016.

### BACKGROUND OF THE INVENTION

### 1. Field of the Invention

The present invention relates to solar cells, solar panels and the like, and particularly to a dye-sensitized solar panel including an extract of chard (the cicla cultivar group of B. vulgaris subsp. cicla).

### 2. Description of the Related Art

A dye-sensitized solar cell (DSSC) is a type of solar cell belonging to the group of thin film solar cells. The dye-sensitized solar cell has a number of attractive features, such as its relatively easy and low-cost manufacture, typically by conventional roll-printing techniques. Most dye-sensitized solar cells are also semi-flexible and semi-transparent, offering a variety of uses which are typically not applicable to glass-based systems.

The performance of the DSSC is mainly based on the dye sensitizer, which acts as an electron pump to transfer the sunlight energy into electron potential. Natural photo-sensitizers have become a viable alternative to other sensitizers because of their low cost, abundance, and little or no associated environmental threat. Intensive research efforts have been directed toward the application of several highly efficient light-harvesting photosynthetic pigment-protein complexes, including reaction centers, photosystem I (PSI), and photosystem II (PSII), as key components in the light-triggered generation of fuels or electrical power. Thus, a dye-sensitized solar panel with a natural dye solving the aforementioned problems is desired.

### SUMMARY OF THE INVENTION

A dye-sensitized solar panel includes a titanium nanoparticle layer and a plant-derived photo-sensitizer supported on the titanium nanoparticle layer. The photo-sensitizer can be extracted from chard (the cicla cultivar group of B. vulgaris subsp. cicla), and the titanium nanoparticle layer includes titanium nanoparticles synthesized using henna (Lawsonia inermis). The titanium nanoparticle layer can, in addition to titanium nanoparticles, include zinc oxide nanoparticles.

These and other features of the present invention will become readily apparent upon further review of the following specification and drawing.

### BRIEF DESCRIPTION OF THE DRAWINGS

The sole drawing FIGURE is a side view in section of a dye-sensitized solar panel with an organic chromophore according to the present invention.

Similar reference characters denote corresponding features consistently throughout the attached drawing.

### DETAILED DESCRIPTION OF THE PREFERRED EMBODIMENTS

A dye-sensitized solar panel 10 includes a titanium nanoparticle layer and a plant-derived photo-sensitizer supported on the titanium nanoparticle layer. The photo-sensitizer can be extracted from the cicla cultivar group of B. vulgaris subsp. cicla, i.e., the cultivar group for the leafy spinach. The titanium nanoparticle layer includes titanium nanoparticles synthesized using henna (Lawsonia inermis). The titanium nanoparticle layer can, in addition to titanium nanoparticles, include zinc oxide nanoparticles.

It is important to note that B. vulgaris subsp. cicla generally includes two different cultivar groups: the cicla cultivar group (i.e., the leafy spinach beet) and the flavescens cultivar group (i.e., stalky Swiss chard). Here, the organic photosensitizing dye is extracted from the cicla cultivar group of B. vulgaris subsp. cicla (i.e., the leafy spinach beet).

As shown in the sole FIGURE, the dye-sensitized solar panel 10 can include first and second transparent substrates 12, 18, respectively, each having opposed inner and outer surfaces. The first and second transparent substrates may be formed from any type of transparent glass or other transparent material, such as fluorine-doped tin oxide, as is well known in the construction of dye-sensitized solar panels.

A working electrode is mounted on the inner surface 26 of the first transparent substrate 12. The working electrode includes a metal electrode 14 (with a resistance preferably less than 30 Ω) and a titanium nanoparticle layer 16 formed thereon. The titanium nanoparticle layer 16 includes titanium nanoparticles synthesized using henna (Lawsonia inermis) dye or extract as a reducing agent. The photosensitizer layer is also supported on the titanium nanoparticle layer 16 which, as noted above, includes B. vulgaris subsp. cicla dye extracted from the cicla cultivar group of B. vulgaris subsp. cicla.

As in a conventional dye-sensitized solar panel, a counter electrode is mounted on the inner surface 28 of the second transparent substrate 18. The counter electrode includes a metal plate 20 formed on the inner surface 28 of the second transparent substrate 18. The metal plate 20 can be coated with a layer of graphite or the like. An electrolyte 22 is sandwiched between the working electrode and the counter electrode, and the panel 10 is preferably sealed with a suitable seal 24, gasket or the like to prevent leakage of the electrolyte 22. The electrolyte may be any suitable type of electrolyte used in the construction of dye-sensitized solar panels, such as lemon juice or the like.

In order to prepare the henna (Lawsonia inermis) extract or dye, Lawsonia inermis leaves were collected from the city of Aldamer in the Republic of the Sudan. The leaves were thoroughly washed with water to remove dust from their surfaces. 100 g of the leaves were dried and ground, producing a henna powder. The henna powder was soaked in 100 mL of warm distilled water and left for 24 hours. The solution was then filtered and used for the dye solution. The dye solution had a dark red color.

The dye or extract obtained from the cicla cultivar group of B. vulgaris subsp. cicla was made by washing half of a conventional sized bag of B. vulgaris subsp. cicla leaves (i.e., leaves from the leafy spinach beet), and then blending the leaves in approximately 100 mL of water. The leaves were ground in the water for between 5 and 10 minutes until the leaves were thoroughly blended. The blended leaves in the water were then centrifuged at 9,000 rpm for 10 minutes to provide the B. vulgaris subsp. cicla dye or extract. The B. vulgaris subsp. cicla dye, extracted from leaves of the cicla cultivar group thereof, is green in color.

In order to synthesize the titanium nanoparticles, titanium (IV) isopropoxide and the henna dye extract were mixed together at a volume ratio of 1:2, respectively, under vigorous magnetic stirring, yielding a red paste. The paste was dried at 60° C. for seven hours, and then at 400° C., resulting in a red powder of titanium nanoparticles. The dyed titanium nanoparticles had an average diameter of 71.33 nm. Similarly, in order to synthesize the zinc oxide nanoparticles, 0.1 M of zinc acetate was dissolved in the henna extract and kept under constant and vigorous magnetic stirring at 70° C. until completely dissolved. After complete dissolution of the zinc acetate, 0.1 M sodium hydroxide (NaOH) aqueous solution was added under constant high-speed stirring, drop by drop, yielding a red paste. The paste was dried in an oven at about 400° C., resulting in a powder of zinc oxide nanoparticles. The zinc oxide nanoparticles had an average diameter of 166.1 nm.

### EXAMPLE 1

A control sample was prepared using titanium nanoparticles synthesized with henna (Lawsonia inermis) extract as a reducing agent, but without the B. vulgaris subsp. cicla dye sensitizer. The titanium nanoparticles were prepared as a paste in nitric acid and coated on a first transparent substrate, formed from fluorine-doped tin oxide. A metal electrode was attached to the first transparent substrate. The paste was left to dry, forming a titanium nanoparticle layer. Small drops of lemon juice were then applied as the electrolyte. A metal plate was coated with graphite (obtained from a pencil) to form the counter electrode, which was mounted on a second transparent substrate, also formed from fluorine-doped tin oxide. The coated sides of the two substrates were brought together, but offset so that uncoated glass extended beyond the sandwich. The metal electrode did not completely cover inner surface of the substrate. A seal was applied on all sides to prevent leakage of the electrolyte.

The sample solar panels were exposed to light from a volt lamp (emitting a mean intensity of 700 lux) and then tested for current and voltage using a microvolt digital multimeter, such as the Model 177 Microvolt DMM, manufactured by Keithley Instruments, Inc. of Cleveland, Ohio. The solar panel was connected to a series of potentiometers with resistance values ranging from 100Ω to 1000Ω. The microvolt digital multimeter measured current and voltage for each load. The values for current and voltage were calculated and measured for maximum current (Iₘ), maximum voltage (Vₘ), open circuit voltage (V_{oc}), and the short circuit current (I_{sc}), and these values were used to calculate the fill factor (FF) and the overall energy conversion efficiency (η). The conversion efficiency (η) is calculated as

$$η = \frac{{I}_{m} \times {V}_{m}}{input power} \times 100 \% ,$$

and the fill factor (FF) is calculated as

$$FF = \frac{{I}_{m} \times {V}_{m}}{{I}_{sc} \times {V}_{oc}}$$

For the control sample, the maximum voltage was 0.083 V, the maximum current was 0.025 A, the short circuit current was 0.1 A, and the open circuit voltage was 0.12 V. Thus, for the control sample without the B. vulgaris subsp. cicla chromophore dye, the conversion efficiency was 2% and the fill factor was 0.0215.

### EXAMPLE 2

In a second example, a sample solar panel was prepared using the titanium nanoparticles synthesized using henna (Lawsonia inermis) extract as a reducing agent and with the dye extracted from the cicla cultivar group of B. vulgaris subsp. cicla, formed into the dye sensitizer layer, supported thereon. The titanium nanoparticles were prepared as a paste in nitric acid and coated on a first transparent substrate to which a metal electrode was mounted. The first substrate was formed from fluorine-doped tin oxide. The paste was left to dry, forming the titanium nanoparticle layer. The coated first substrate with the titanium nanoparticle layer was soaked in the B. vulgaris subsp. cicla dye for a period of 24 hours for adsorption of sufficient dye onto the titanium nanoparticle layer to form a sensitizer. The structure was then rinsed with ethanol to remove any excess dye and, when dry, small drops of lemon juice were applied as the electrolyte. A metal plate was coated with graphite (obtained from a pencil) to form a counter electrode, which was mounted on a second transparent substrate, also formed from fluorine-doped tin oxide. The coated sides of the two substrates were brought together, but offset so that uncoated glass extends beyond sandwich. The metal electrode did not completely cover inner surface of the substrate. A seal was applied on all sides to prevent leakage of the electrolyte.

The sample solar panel was tested in a manner identical to the control sample of Example 1. For the sample solar panel of Example 2, the maximum voltage was 0.284 V, the maximum current was 0.025 A, the short circuit current was 0.4 A, and the open circuit voltage was 0.245 V. Thus, for the sample solar panel with the B. vulgaris subsp. cicla dye, the conversion efficiency was 67% and the fill factor was 0.7245.

### EXAMPLE 3

In a third example, a sample solar panel was prepared using a composite of titanium nanoparticles synthesized with henna (Lawsonia inermis) extract as a reducing agent and zinc oxide nanoparticles synthesized with henna (Lawsonia inermis) extract as a reducing agent, with the B. vulgaris subsp. cicla (cicla cultivar) chromophore dye supported thereon. 0.5 g of the titanium nanoparticles and the zinc oxide nanoparticles were mixed together and ground in a pestle and a few drops of nitric acid were added to form a paste.

The paste was coated on a first transparent substrate to which a metal electrode was mounted. The first transparent substrate was formed from fluorine-doped tin oxide. The paste was left to dry, forming the composite nanoparticle layer. The coated first substrate with the composite nanoparticle layer was soaked in the B. vulgaris subsp. cicla (cicla cultivar) dye for a period of 24 hours to adsorb enough of the dye onto the composite nanoparticle layer to provide a sensitizer. The structure was then rinsed with ethanol to remove any excess dye and, when dry, small drops of lemon juice were applied as the electrolyte. A metal plate was coated with graphite (obtained from a pencil) to form the counter electrode, which was mounted on the second transparent substrate, also formed from fluorine-doped tin oxide. The coated sides of the two substrates were brought together, but offset so that uncoated glass extended beyond the sandwich. The metal electrode did not completely cover inner surface of the substrate. A seal was applied on all sides to prevent leakage of the electrolyte.

The sample solar panel was tested in a manner identical to the samples of Example 1 and Example 2. For the sample solar panel of Example 3, the maximum voltage was 0.445 V, the maximum current was 0.021 A, the short circuit current was 0.16 A, and the open circuit voltage was 0.3 V. Thus, for the sample solar panel with the B. vulgaris subsp. cicla (cicla cultivar) chromophore dye supported on the composite of titanium oxide and zinc oxide nanoparticles, the conversion efficiency was 33% and the fill factor was 0.1947.

In each of the above examples, the input power was calculated from the known intensity of the lamp and illuminated area of each solar panel, which was (1×2) cm². From the above, one can see that the energy conversion efficiency is highest (67%) for the sample including just titanium oxide nanoparticles (with the B. vulgaris subsp. cicla dye supported thereon), and second highest (33%) for the composite of titanium oxide and zinc oxide nanoparticles (with the B. vulgaris subsp. cicla dye supported thereon). These are compared against the 2% conversion efficiency of the control sample, which did not have the B. vulgaris subsp. cicla dye.

It is to be understood that the present invention is not limited to the embodiments described above, but encompasses any and all embodiments within the scope of the following claims.

We claim:

1. A dye-sensitized solar panel, comprising:
a first transparent substrate having opposed inner and outer surfaces;
a working electrode mounted on the inner surface of the first transparent substrate, the working electrode comprising:
a metal electrode;
a titanium nanoparticle layer; and
an organic photosensitizing dye supported on the titanium nanoparticle layer, wherein the photosensitizing dye comprises dye extracted from a cicla cultivar group of B. vulgaris subsp. cicla;
a second transparent having opposed inner and outer surfaces;
a counter electrode mounted on the inner surface of the second transparent substrate, the counter electrode comprising a conductive layer; and
an electrolyte sandwiched between the working electrode and the counter electrode.

2. The dye-sensitized solar panel as recited in claim 1, wherein said first and second transparent substrates each comprise fluorine-doped tin oxide.

3. The dye-sensitized solar panel as recited in claim 2, wherein said conductive layer of said counter electrode comprises graphite.

4. The dye-sensitized solar panel as recited in claim 3, wherein said electrolyte comprises lemon juice.

5. The dye-sensitized solar panel as recited in claim 1, wherein said titanium nanoparticle layer further includes zinc oxide nanoparticles.

6. The dye-sensitized solar panel as recited in claim 1, wherein said titanium nanoparticles are synthesized using a Lawsonia inermis dye as a reducing agent.

7. The dye-sensitized solar panel as recited in claim 1, wherein the metal electrode has a resistance less than 30Ω.

8. A method of making a dye-sensitized solar panel, comprising the steps of:
securing a metal electrode to an inner surface of a first transparent substrate;
coating the metal electrode with a titanium nanoparticle layer to form a coated first substrate, the titanium nanoparticle layer including titanium nanoparticles synthesized using Lawsonia inermis extract as a reducing agent;
soaking the coated first substrate in an organic photosensitizing dye to adsorb the organic photosensitizing dye therein, the photosensitizing dye comprising dye extracted from a cicla cultivar group of B. vulgaris subsp. cicla dye;
mounting a counter electrode to an inner surface of a second transparent substrate; and
sandwiching an electrolyte between the working electrode and the counter electrode.

9. The method of making a dye-sensitized solar panel as recited in claim 8, wherein the step of soaking the coated first substrate in the organic photosensitizing dye comprises soaking the coated first substrate in the organic photosensitizing dye for 24 hours.

10. The method of making a dye-sensitized solar panel as recited in claim 8, wherein the step of mounting the counter electrode to the inner surface of the second transparent substrate comprises mounting a graphite layer to the inner surface of the second transparent substrate.

11. The method of making a dye-sensitized solar panel as recited in claim 8, wherein the step of sandwiching the electrolyte between the working electrode and the counter electrode comprises sandwiching lemon juice between the working electrode and the counter electrode.

12. The method of making a dye-sensitized solar panel as recited in claim 8, wherein the titanium nanoparticle layer further includes zinc oxide nanoparticles synthesized using Lawsonia inermis extract as a reducing agent.

13. The method of making a dye-sensitized solar panel as recited in claim 8, further comprising the steps of:
blending leaves of the cicla cultivar group of B. vulgaris subsp. cicla in water;
centrifuging the blended leaves of the cicla cultivar group of B. vulgaris subsp. cicla in the water; and
extracting the dye extracted from the cicla cultivar group of B. vulgaris subsp. cicla.
